(19) United States
(12) Patent Application Publication
(10) Pub. No.: US 2011/0031513 A1
(43) Pub. Date: Feb. 10, 2011

(54) WATERPROOF SMD LED MODULE AND METHOD OF MANUFACTURING THE SAME

(75) Inventors: MIN-TSUN HSIEH, Hukou (TW); LUNG-HSIN CHEN, Hukou (TW); SHEN-BO LIN, Hukou (TW); CHING-LIEN YEH, Hukou (TW); CHIH-YUNG LIN, Hukou (TW)

Correspondence Address: Altis Law Group, Inc.;ATTN: Steven Reiss, 288 SOUTH MAYO AVENUE, CITY OF INDUSTRY, CA, 91789, US

(73) Assignee: ADVANCED OPTOELECTRONIC TECHNOLOGY, INC., Hsinchu Hsien (TW)

(21) Appl. No.: 12/835,727

(22) Filed: Jul. 13, 2010

(30) Foreign Application Priority Data
Aug. 4, 2009 (TW) 98126211

(51) Int. Cl. H01L 33/48; H01L 33/60; H01L 33/44; H01L 33/62

(52) U.S. Cl. 257/88; 257/98; 438/26; 257/99; 257/E33.059; 257/E33.066; 257/E33.061; 257/E33.067

(57) ABSTRACT

A surface-mount device (SMD) light emitting diode (LED) module includes a leadframe, an LED chip, a waterproof protective film and a sealing material. The leadframe includes a plurality of leads and the LED chip is fixed on one of the leads. The waterproof protective film covers the LED chip and a portion of the leadframe, and exposes a portion of the leadframe for connecting to a circuit board. The sealing material is also formed on the leadframe to cover the LED chip. In addition, a method of manufacturing the SMD LED module is provided.

### BACKGROUND

1. Technical Field

The present disclosure relates to light emitting diodes (LED), and particularly, to a surface-mount device (SMD) LED module and a method of manufacturing the same.

2. Description of Related Art

LEDs are extensively applied to illumination devices due to high brightness, low working voltage, low power consumption, compatibility with integrated circuitry, simple driving operation, long lifetime and other factors.

LEDs have replaced incandescent lamps in many interior and outdoor illuminations, such as Christmas decorations, display window decorations, interior lamps, landscaping, streetlamps and traffic signs. As such, LEDs work in various conditions. However, some conditions are too harsh for the related LEDs package, and thereby decrease the lifetime thereof.

Therefore, it is desirable to provide an LED module which can overcome the described limitations.

### BRIEF DESCRIPTION OF THE DRAWINGS

Many aspects of the disclosure can be better understood with reference to the drawings. The modules in the drawings are not necessarily drawn to scale, the emphasis instead being placed upon clearly illustrating the principles of the present image capture device and control method thereof. Moreover, in the drawings, like reference numerals designate corresponding parts throughout the views.

FIG. 1 is a flowchart illustrating a method of manufacturing a waterproof SMD LED module according to a first embodiment of the present disclosure.

FIG. 2A through FIG. 2F are cross sections of the waterproof SMD LED module at different manufacturing steps of the method of FIG. 1.

FIG. 3 is a cross section of a waterproof SMD LED module according to a second embodiment of the present disclosure.

FIG. 4 is a flowchart illustrating a method of manufacturing the waterproof SMD LED module of FIG. 3.

FIG. 5 is a cross section of a waterproof SMD LED module according to a third embodiment of the present disclosure.

FIG. 6 is a cross section of a waterproof SMD LED module according to a fourth embodiment of the present disclosure.

FIG. 7 is a cross section of a waterproof SMD LED module according to a fifth embodiment of the present disclosure.

### DETAILED DESCRIPTION

The present disclosure relates to a waterproof SMD LED module and a manufacturing method thereof, the waterproof SMD LED module characterized by a waterproof protective film. Embodiments of the disclosure will now be described in detail with reference to the accompanying drawings.

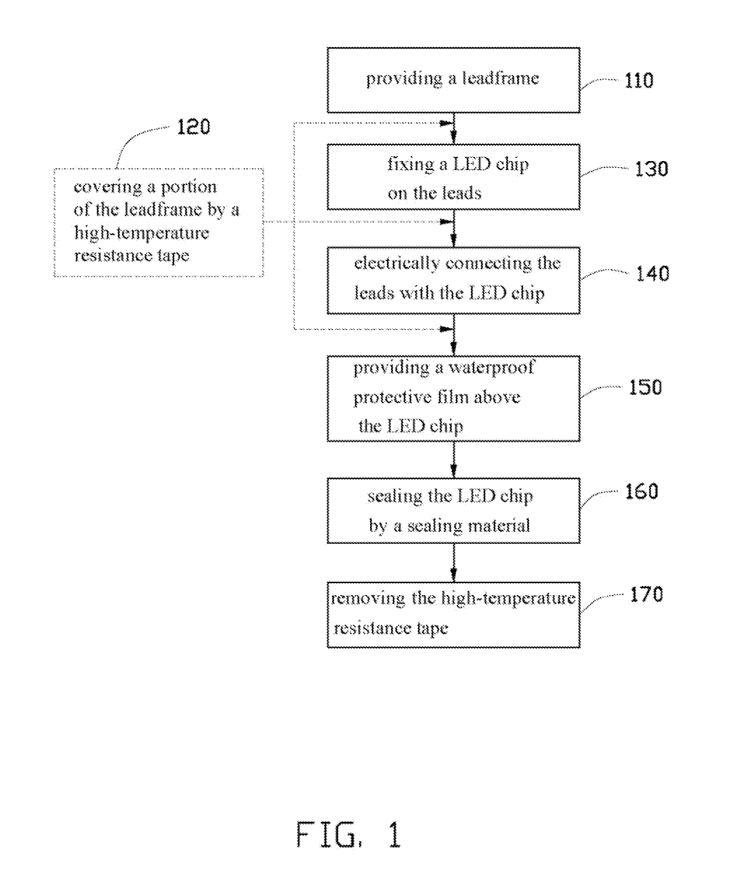

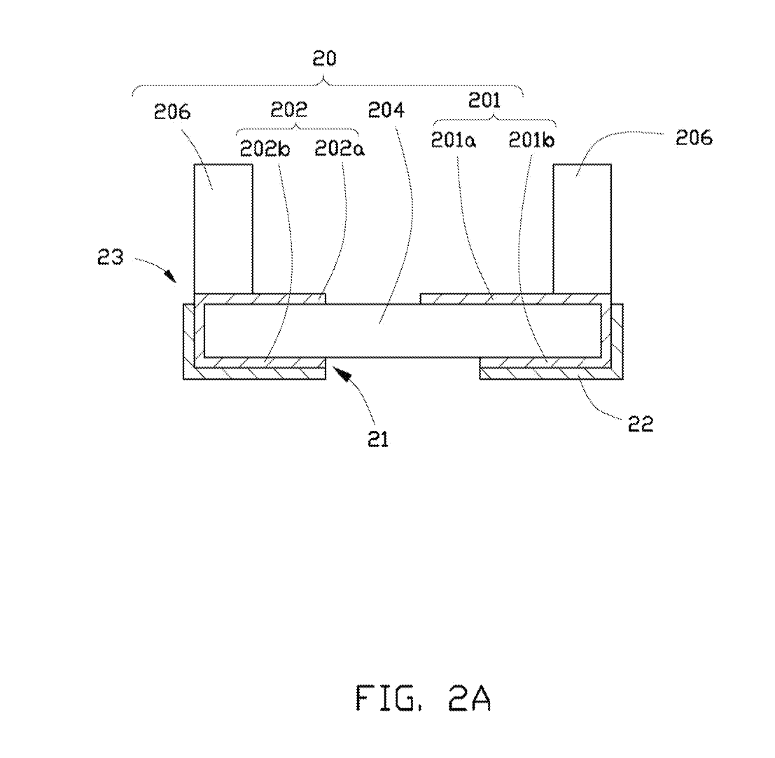

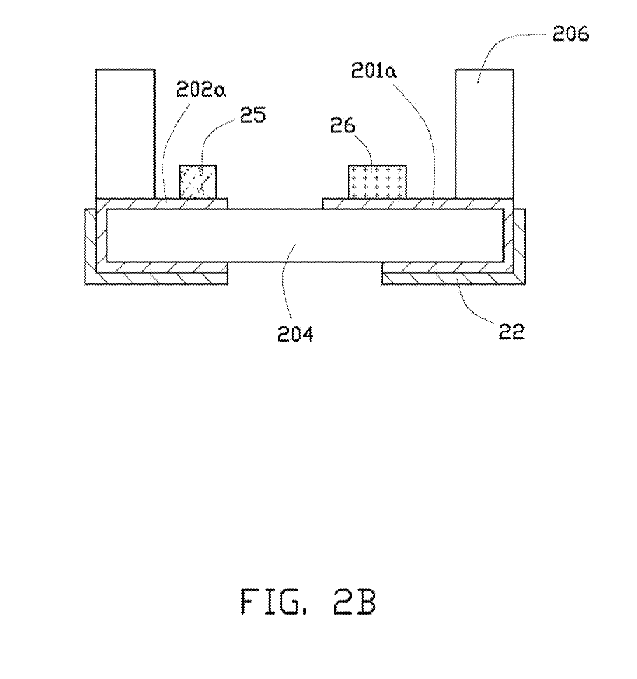

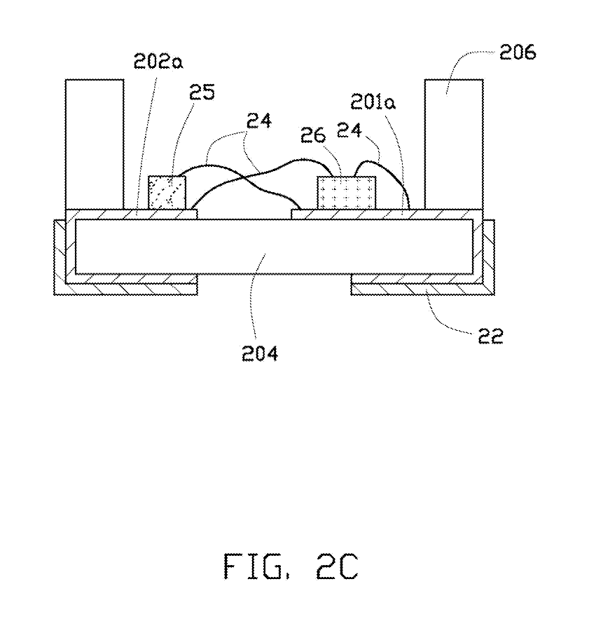

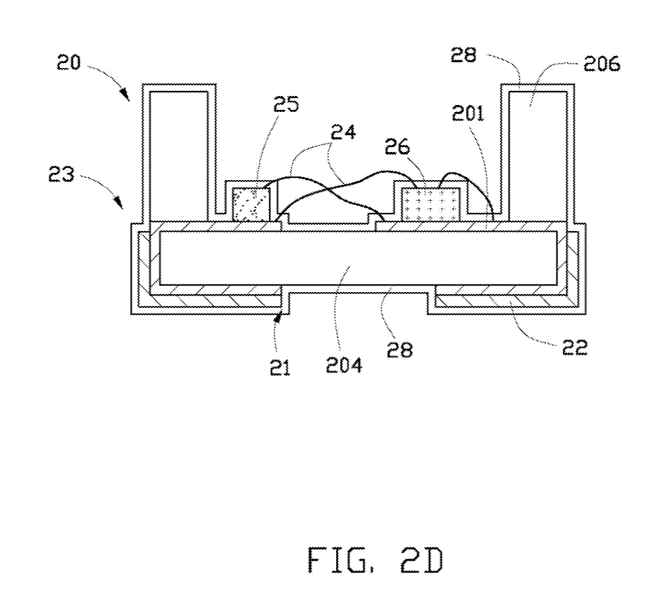

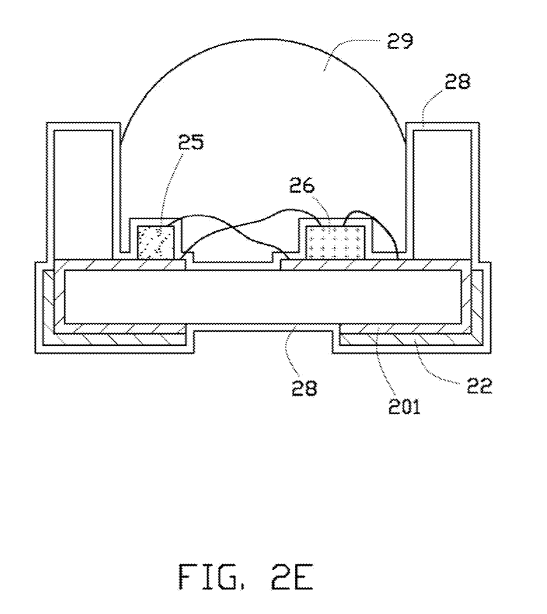

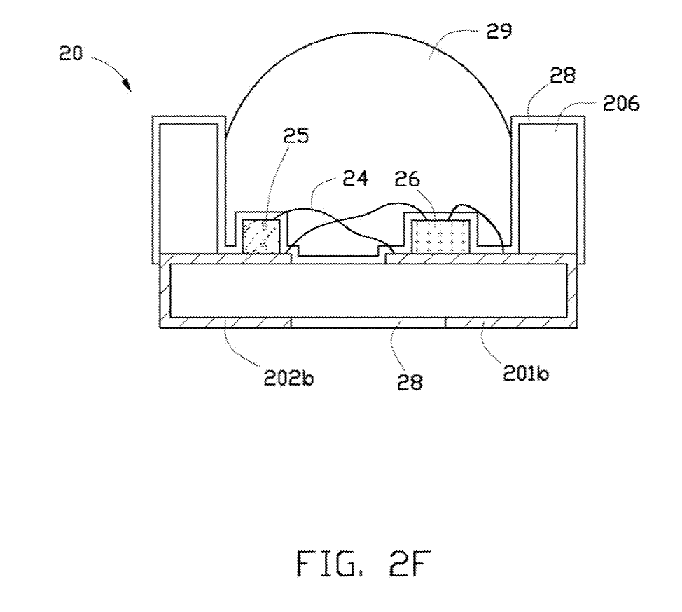

Referring to FIG. 1 and FIG. 2A, a leadframe 20 is provided in step 110. The leadframe 20 includes a plurality of leads for electrical connection, such as lead 201 and lead 202. It is noted that the leadframe 20 may include a plurality of leads 201 and a plurality of leads 202 in other embodiments.

The leadframe 20 may further include a carrier 204 for supporting an LED chip 26 (FIG. 2B), and a reflective cup 206 for surrounding the LED chip 26. The carrier 204 and the reflective cup 206 may be formed simultaneously on the leads 201 and 202 by injection molding. Alternatively, the leads 201 and 202 and the reflective cup 206 may be formed individually, and combined to the carrier 204 in order. The leads 201 and 202 can include any conductive materials, such as copper, nickel or alloy thereof. The reflective cup 206 can include any heatproof or reflective materials, such as metals, polyphthalamide (PPA) or other plastics.

Each lead 201 or 202 may be divided into at least two portions. Each lead 201 includes an inner lead 201a and an outer lead 201b; and each lead 202 includes an inner lead 202a and an outer leads 202b. The inner leads 201a and 202a are substantially the portions located inside the reflective cup 206 for electrical connection to at least one following-arranged LED chip by a surface-mount process; the outer leads 201b and 202b are substantially the portions extending outside the reflective cup 206 and the top surface of the carrier 204 for electrical connection to a circuit board.

The outer leads 201b and 202b are covered by a high-temperature resistant tape 22 in step 120 and FIG. 2A, so the exposed portions of the leads 201 and 202 are protected during manufacture to ensure conductivity. The high-temperature resistant tape 22 may be attached to the outer leads 201b and 202b at any time before a waterproof protective film is deposited. For example, the high-temperature resistant tape 22 may be adhered before the leads 201 and 202 are combined to the carrier 204; after the leads 201 and 202 are combined to the carrier 204 and before the LED chip 26 is fixed; or after the LED chip 26 is electrically connected to the leads 201 and 202.

The high-temperature resistant tape 22 can expose the boundaries 21 between the carrier 204 and the leads 201 and 202, and the boundaries 23 between the reflective cup 206 and the leads 201 and 202. As such, the subsequently formed waterproof protective film can cover the exposed boundary 21 and the boundaries 23 to prevent moisture from penetrating the module through the interstices.

The LED chip 26 is provided and fixed on the leadframe 20 in step 130 and FIG. 2B. The LED chip 26 may be located on the inner lead 201a, but is not limited thereto. A zener diode 25 may also be fixed on the inner leads 202a in step 130 and FIG. 2B.

A wire bonding process is performed in step 140 and FIG. 2C for electrical connection to the LED chip 26. Specifically, two electrodes of the LED chip 26 are electrically connected to the inner lead 201a and the inner lead 202a respectively through golden wires 24. As shown in step 140 and FIG. 2C, the zener diode 25 is also electrically connected to the inner lead 201a through the golden wire 24. A bottom of the zener diode 25 is soldered on the inner lead 202a.

A waterproof protective film 28 is deposed on the semi-finished SMD LED module to repel external water or moisture in step 150 and FIG. 2D. The waterproof protective film 28 can be located on both the top surface and bottom surface of the leadframe 20. Accordingly, the waterproof protective film 28 covers the reflective cup 206, the carrier 204, the leads 201 and 202, the LED chip 26, the zener diode 25, the boundary 21 and the boundary 23 to prevent moisture from penetrating the module. The electric components and circuits in the SMD LED module, such as the LED chip 26, the zener diode 25, the golden wires 24 and the leads 201 and 202, are all protected, and the reliability and quality of the SMD LED module are ensured.

The waterproof protective film 28 may be a transparent thin film deposed by a chemical vapor deposition (CAD) process, physic vapor deposition (PAD) process, vacuum evaporation process, sputtering deposition process, or dip coating process performed through sol-gel technology. The thickness of the waterproof protective film 28 can be in a range from about 1 micrometer to about 20 micrometers, and particularly from about 15 micrometers to about 20 micrometers. The waterproof protective film 28 may include poly-para-xylylene (parylene), polyimide (PI), semi-crystalline parylene-based, metal nitride, aluminum oxide (Al₂O₃), polymethylmethactylate (PMMA), a compound of PI and Al₂O₃, diamond-like carbon (DLC) or any combination thereof.

The waterproof protective film 28 may cover the whole semi-finished SMD LED module, but is not limited thereto. For example, the waterproof protective film 28 may not cover the high-temperature resistant tape 22 in other embodiments.

The LED chip 26 and the corresponding electric components are sealed by a sealing material 29 in step 160 and FIG. 2E, providing further protection for the LED chip 26. The sealing material 29 may include epoxy resin or silicone gel, and may include phosphors or fluorescence to convert the color of the light emitted from the LED chip 26 into another color.

The high-temperature resistant tape 22 is removed from the leadframe 20 in step 170 and FIG. 2F after the sealing material 29 is formed. The portions of the waterproof protective film 28 located on the high-temperature resistant tape 22 are also removed simultaneously as soon as the high-temperature resistant tape 22 is peeled from the leadframe 20. Thus, the outer leads 201b and 202b are exposed for electrical connection, and thereby the SMD LED module of the disclosure is formed.

It is noted that the high-temperature resistance tape 22 may be replaced by any other tape, removable materials or fixtures. The requirement is that when the other tape, removable materials or fixtures are removed from the leadframe 20, the portion of the waterproof protective film 28 thereon is removed therewith to expose the outer leads 201b and 202b. In a further embodiment, the high-temperature tape 22 is not necessary, and the application of the waterproof protective film 28 to the SMD LED module excludes the application to the outer leads 201b, 202b during the manufacturing.

According to the disclosure, the water-resistance of the SMD LED module is improved. The electric components and circuits in the SMD LED module, such as the LED chip 26, the zener diode 25, the golden wires 24 and the leads 201 and 202, are all enclosed by the waterproof protective film 28, and the lifetime, reliability and quality of the SMD LED module are ensured.

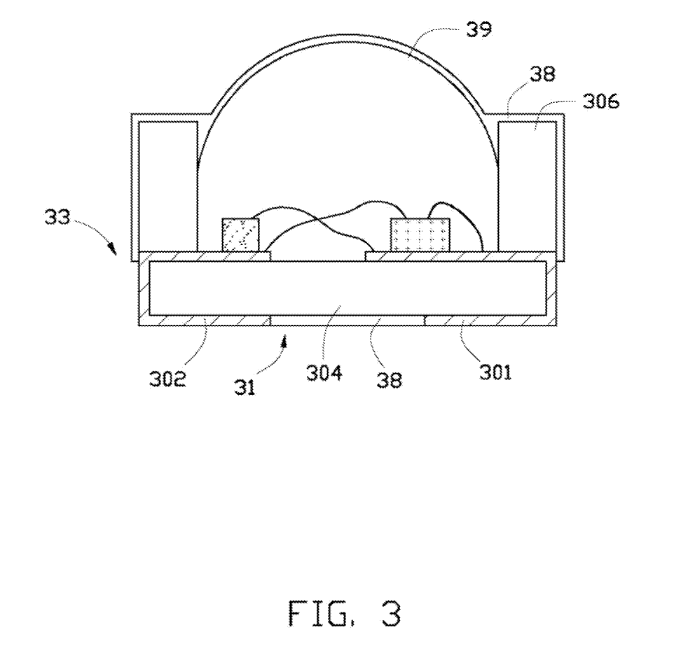

The performing order and processes of the steps as disclosed may be adjusted as required. For instance, step 170 of removing the high-temperature resistant tape 22 may be carried out before the sealing material 29 is formed. Another embodiment with different order is shown in FIG. 3.

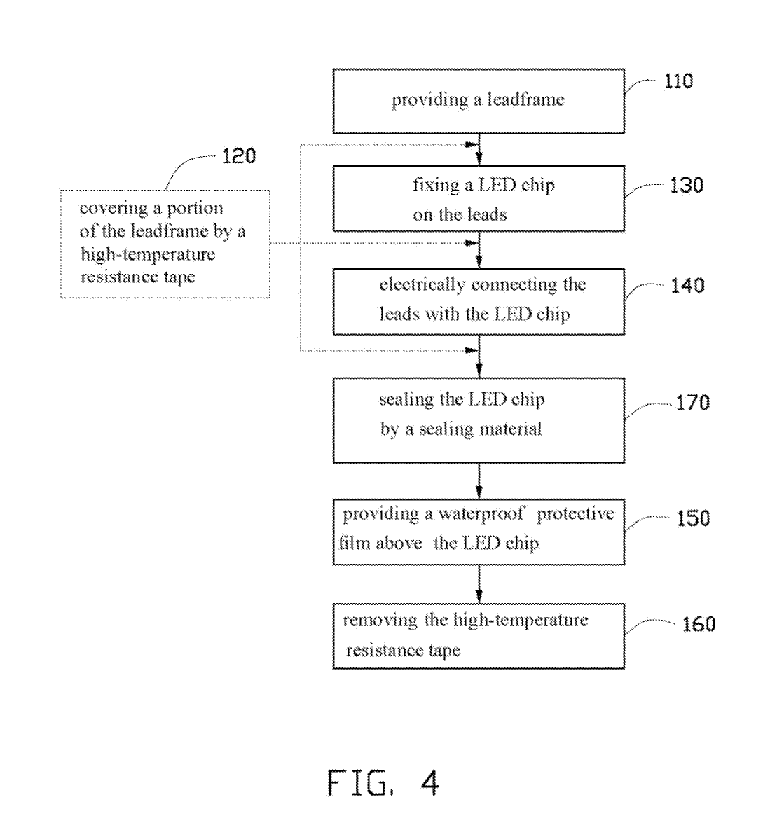

As shown in FIG. 3 and FIG. 4, the main differences between the second embodiment and the first embodiment is that the sealing material 39 is formed before the waterproof protective film 38 is deposited in this embodiment. Thereafter, the high-temperature resistant tape (not shown in FIG. 3) is removed from the leads 301 and 302. As such, the waterproof protective film 38 also covers the sealing material 39, in addition to the reflective cup 306, the carrier 304 and the leads 301 and 302 externally, the boundaries 31 between the carrier 304 and the leads 301 and 302, and the boundaries 33 between the reflective cup 306 and the leads 301 and 302, which are already protected by the waterproof protective film 38.

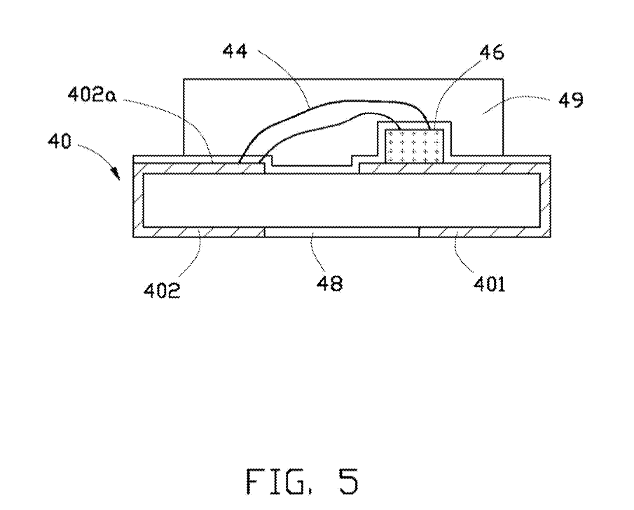

As shown in FIG. 5, the main differences between the third embodiment and the first embodiment includes the structure of the leadframe 40, the absence of the zener diode, the connections of golden wires 44 and the shape of the sealing material 49. The leadframe 40 includes no reflective cup surrounding the LED chip 46, and the SMD LED module includes no zener diode electrically connected to the leads 401, 402. The LED chip 46 may be electrically connected to the inner leads 402a located at the opposite side through golden wire 44. The waterproof protective film 48 covers the whole leadframe including the LED chip 46 and exposing leads 402 and 401. Then, a sealing material 49 is overlaid on the waterproof protective film. The sealing material 49 may be cured with a flat top surface, but is not limited thereto.

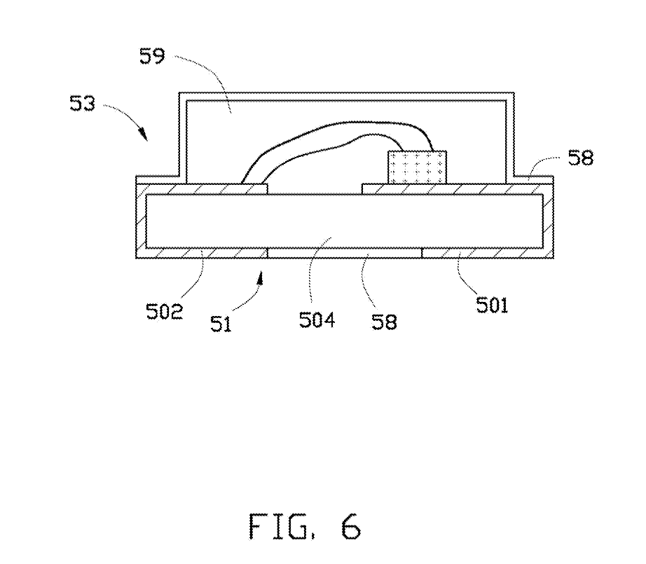

As shown in FIG. 6, the main differences between the fourth embodiment and the third embodiment is that the sealing material 59 is formed before the waterproof protective film 58 is deposited in this embodiment. As such, the waterproof protective film 58 also covers sealing material 59, in addition to the boundary 53 between the sealing material 59 and the leads 501 and 502, and the boundary 51 between the carrier 504 and the leads 501 and 502.

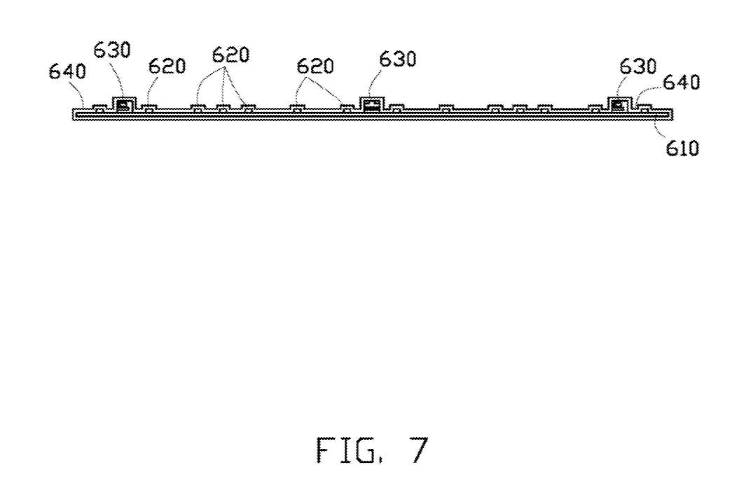

As shown in FIG. 7, the main differences between the fifth embodiment and the previous embodiments is that the LED components 620 are electrically connected to a circuit board 610 before the waterproof protective film 640 is deposited. The LED components 620 may be LED chips, small LED modules, the previously disclosed SMD LED modules or other LED components. The waterproof protective film 640 encloses the LED components 620, the electronic components 630, and the circuit board 610, but is not limited thereto. The formed SMD LED module may be an LED light bar or an LED array module. Furthermore, electronic components 630 are not limited on the PCB.

The waterproof protective film 640 may expose portions of the LED components 620 and the electronic components 630 in other embodiments. For example, the waterproof protective film 640 may merely cover the circuit board 610, or merely the circuit board 610, the boundaries between the circuit board 610 and the LED components 620, and the boundaries between the circuit board 610 and the electronic components 630.

In sum, the SMD LED module of the present disclosure includes the waterproof protective film to improve waterproof capability. Many variations are possible and do not alter the spirit of the present disclosure. The figures described herein are by way of example and not limitation. For example, the number of LED chips can be adjusted as required, or the LED components and the electronic components may be electrically connected to the substrate or the circuit board through flip chip package.

Accordingly, the waterproof protective film improves the water-resistance of the SMD LED module. The electric components and circuits in the SMD LED module are protected, and the lifetime, reliability and quality of the SMD LED module are ensured.

It is to be understood, however, that even though numerous characteristics and advantages of various embodiments have been set forth in the foregoing description, together with details of the structures and functions of the embodiments, the disclosure is illustrative only; and that changes may be made in detail, especially in matters of arrangement of parts within the principles of the invention to the full extent indicated by the broad general meaning of the terms in which the appended claims are expressed.

What is claimed is:

1. A waterproof surface-mount device (SMD) light emitting diode (LED) module, comprising:
a leadframe, comprising a plurality of leads;
at least one LED chip fixed on one of the leads;
a waterproof protective film covering the LED chip and a portion of the leadframe and exposing portions of the leads for electrically connecting to an external device; and
a sealing material formed on the leadframe to cover the LED chip.

2. The SMD LED module of claim 1, wherein the leadframe comprises a carrier supporting the LED chip, and the waterproof protective film covers the carrier and a boundary between the carrier and the leads.

3. The SMD LED module of claim 2, wherein the leadframe further comprises a reflective cup surrounding the LED chip, and the waterproof protective film covers the reflective cup and a boundary between the reflective cup and the leads.

4. The SMD LED module of claim 1, wherein the waterproof protective film is located between the sealing material and the LED chip.

5. The SMD LED module of claim 1, wherein the sealing material is located between the waterproof protective film and the LED chip.

6. The SMD LED module of claim 1, wherein the sealing material comprises a phosphor.

7. The SMD LED module of claim 1, wherein the waterproof protective film covers a top surface of the leadframe on which the LED chip is located.

8. The SMD LED module of claim 7, wherein the waterproof protective film covers a bottom surface of the leadframe opposite to the top surface.

9. The SMD LED module of claim 1, wherein a thickness of the waterproof protective film is in a range from about 1 micrometer to about 20 micrometers.

10. The SMD LED module of claim 1, wherein the waterproof protective film is selected from a group consisting of poly-para-xylylene (parylene), polyimide (PI), semi-crystalline parylene-based, metal nitride, aluminum oxide (Al₂O₃), polymethylmethactylate (PMMA), a compound of PI and Al₂O₃, and diamond-like carbon (DLC).

11. A waterproof LED module, comprising:
a substrate;
a plurality of LED components disposing on the substrate; and
a waterproof protective film overlaying on the substrate and the plurality of LED components.

12. The waterproof LED module of claim 11, wherein a thickness of the waterproof protective film is in a range from about 1 micrometers to about 20 micrometers

13. The waterproof LED module of claim 11, wherein the waterproof protective film is selected from a group consisting of poly-para-xylylene (parylene), polyimide (PI), semi-crystalline parylene-based, metal nitride, aluminum oxide (Al₂O₃), polymethylmethactylate (PMMA), a compound of PI and Al₂O₃, and diamond-like carbon (DLC).

14. A method of manufacturing a waterproof surface-mount device (SMD) light emitting diode (LED) module, comprising:
providing a leadframe, the leadframe comprising a plurality of leads;
covering a portion of the leadframe with a tape
fixing an LED chip on at least one of the leads;
electrically connecting the leads with the LED chip; and
providing a waterproof protective film enveloping the LED chip.

15. The method of claim 14, further comprising removing the tape to expose the portion of the leadframe after the waterproof protective film is provided enveloping the LED chip.

16. The method of claim 14 further comprising a step of sealing the LED chip with a sealing material after the waterproof protective film is provided enveloping the LED chip.

17. The method of claim 14 further comprising a step of sealing the LED chip with a sealing material before the waterproof protective film is provided enveloping the LED chip.

18. The method of claim 14, wherein the waterproof protective film covers a top surface of the leadframe on which the LED chip is located.

19. The method of claim 17, wherein the waterproof protective film covers a bottom surface of the leadframe opposite to the top surface.

20. The method of claim 14, wherein a thickness of the waterproof protective film is in a range from about 1 micrometer to about 20 micrometers.
